(19) United States
(12) Patent Application Publication
(10) Pub. No.: US 2026/0052813 A1
(43) Pub. Date: Feb. 19, 2026

(54) LENS STRUCTURES IN LIGHT-EMITTING DIODE PACKAGES

(71) Applicant: CreeLED, Inc., Durham, NC (US)

(72) Inventors: David Suich, Durham, NC (US); F James Claire, Chapel Hill, NC (US); Derek Miller, Columbus, OH (US); Colin Blakely, Raleigh, NC (US); Joseph G. Sokol, Durham, NC (US); Robert Wilcox, Rolesville, NC (US)

(21) Appl. No.: 18/806,014

(22) Filed: Aug. 15, 2024

(51) Int. Cl. H01L 33/58; G02B 3/04; H01L 25/075

(52) U.S. Cl. CPC H10H 20/855; G02B 3/04; H01L 25/0753

(57) ABSTRACT

Light-emitting diode (LED) devices and more particularly lens structures in LED packages are disclosed. Lens structures include complex shapes for achieving various emission patterns in LED packages. Complex lens shapes include lens widths that are greater than corresponding widths of support elements, including lead frame structures or submount structures. Complex lens shapes further include inward depressions positioned relative to underlying LED chips for directing peak emission intensities off center relative to LED packages. Exemplary LED packages further include encapsulant layers positioned between lenses and underlying LED chips for providing one or more of improved surfaces for lens formation and improved adhesion.

### FIELD OF THE DISCLOSURE

The present disclosure relates to light-emitting diode (LED) devices, and more particularly to lens structures in LED packages.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new applications, including LED displays and lighting devices for general illumination.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that can provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly to lens structures in LED packages. Lens structures include complex shapes for achieving various emission patterns in LED packages. Complex lens shapes include lens widths that are greater than corresponding widths of support elements, including lead frame structures or submount structures. Complex lens shapes further include inward depressions positioned relative to underlying LED chips for directing peak emission intensities off center relative to LED packages. Exemplary LED packages further include encapsulant layers positioned between lenses and underlying LED chips for providing one or more of improved surfaces for lens formation and improved adhesion.

In one aspect, an LED package comprises: a housing forming a recess with a recess floor; a lead frame structure at least partially within the housing; at least one LED chip positioned on the lead frame structure within the recess; an encapsulant layer within the recess; and a lens on the encapsulant layer and the housing, the lens having a first width that is greater than a second width of the housing. In certain embodiments, a surface of the lens forms an inward depression in a direction toward the at least one LED chip. In certain embodiments, the inward depression is centered with respect to the at least one LED chip. In certain embodiments, a perimeter of the inward depression forms a circular shape. In certain embodiments, a perimeter of the inward depression forms an oval shape. In certain embodiments, the encapsulant layer comprises a lower coefficient of thermal expansion than the lens. In certain embodiments, the recess forms at least one sidewall that extends to the recess floor, and the encapsulant layer covers at least ninety percent of the at least one sidewall. In certain embodiments, the recess forms at least one sidewall that extends to the recess floor, and the encapsulant layer covers a range from fifty to ninety percent of the at least one sidewall, and the lens covers at least a portion of the at least one sidewall. In certain embodiments: the encapsulant layer comprises a first sublayer and a second sublayer; the first sublayer is between the recess floor and the second sublayer; and the first sublayer comprises a higher concentration of lumiphoric particles than the second sublayer. In certain embodiments, the lens forms a circular shape at the first width. In certain embodiments, the lens forms an oval shape at the first width. In certain embodiments: the at least one LED chip comprises at least a first LED chip and a second LED chip; a surface of the lens forms a first inward depression that is centered with respect to the first LED chip; and the surface of the lens forms a second inward depression that is centered with respect to the second LED chip.

In another aspect, an LED package comprises: a support element; at least one LED chip positioned on the support element; and a lens on at least one LED chip and the support element, the lens forming a first width that is greater than a second width of the support element, and the lens further forming an inward depression in a direction toward the at least one LED chip. In certain embodiments, the inward depression is centered with respect to the at least one LED chip. In certain embodiments: the at least one LED chip comprises at least a first LED chip and a second LED chip; the inward depression is a first inward depression that is centered with respect to the first LED chip; and the lens further forms a second inward depression that is centered with respect to the second LED chip. In certain embodiments, the support element comprises a submount with electrically conductive traces. In certain embodiments, the support element comprises a lead frame structure at least partially within a housing. The LED package may further comprise an encapsulant layer between the lens and the at least one LED chip. In certain embodiments, the housing forms a recess with at least one sidewall that extends to a recess floor, and the encapsulant layer covers at least ninety percent of the at least one sidewall. In certain embodiments, the housing forms a recess with at least one sidewall that extends to a recess floor, and the encapsulant layer covers a range from fifty to ninety percent of the at least one sidewall, and the lens covers at least a portion of the at least one sidewall.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a cross-sectional view of a light-emitting diode (LED) package that includes a lead frame structure collectively formed by a plurality of leads, a body or housing that encases a portion of the lead frame structure, at least one LED chip, and a lens with a structure according to principles of the present disclosure.

FIG. 1B is a top view of the LED package of FIG. 1A illustrating a generally circular shape for the lens.

FIG. 1C is a side view of the LED package of FIG. 1A.

FIG. 2 depicts a graph of far-field patterns for various configurations of the LED package of FIGS. 1A to 1C as compared to a control LED package without a lens.

FIG. 3 is a top view of an LED package that is similar to the LED package of FIGS. 1A to 1C, except the lens is formed with an oval shape.

FIG. 4 is a cross-sectional view of an LED package that is similar to the LED package of FIGS. 1A to 1C, except the lens is arranged to extend farther into the recess.

FIG. 5 is a cross-sectional view of an LED package that is similar to the LED package of FIGS. 1A to 1C, except the lens forms multiple depressions.

FIG. 6 is a cross-sectional view of an LED package that is similar to the LED package of FIGS. 1A to 1C, except the LED package includes a submount instead of a lead frame structure.

FIG. 7 is a cross-sectional view of an LED package that is similar to the LED package of FIGS. 1A to 1C with a different shape for the lens.

FIG. 8 is a schematic diagram of a portion of an LED device, such as an LED display, that includes LED packages according to principles of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to lens structures in LED packages. Lens structures include complex shapes for achieving various emission patterns in LED packages. Complex lens shapes include lens widths that are greater than corresponding widths of support elements, including lead frame structures or submount structures. Complex lens shapes further include inward depressions positioned relative to underlying LED chips for directing peak emission intensities off center relative to LED packages. Exemplary LED packages further include encapsulant layers positioned between lenses and underlying LED chips for providing one or more of improved surfaces for lens formation and improved adhesion.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group Ill nitrides. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure can emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B light is typically defined as a peak wavelength range from 280 nm to 315 nm, and UV-C light is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

Aspects of the present disclosure are applicable to both single-chip and multiple-chip LED packages. In multiple-chip LED packages, multiple LED chips are arranged within a common recess or on a common submount and sometimes beneath a common lens of an LED package. In certain embodiments, LED packages may include red, green, and blue LED chips such that the LED package may be positioned as a pixel in an LED display. In other embodiments, aspects of the present disclosure may be applicable to other LED packages, such as those that include one or more LED chips with a recipient lumiphoric material that converts at least a portion of light generated from the one or more LED chips to a different wavelength.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective).

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or element, such as a lead frame structure or a submount.

Lead frame structures are typically at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. In certain embodiments, one or more lumiphoric materials, such as phosphor particles, may be integrated or otherwise embedded within the encapsulant material.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Light-altering materials may be arranged within LED packages to reflect or otherwise redirect light from the one or more LED chips in a desired emission direction or pattern.

Light-altering materials may be arranged within LED packages, such as within housings and/or within portions of recesses thereof, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

In conventional LED packages, lenses are typically formed by a molding process that provides a lens shape on the support structure. The molding process may include confining an encapsulant material to the shape of a lens with a mold block, curing of the encapsulant material, followed by removal of the mold block. In such applications, the shape of the lens may form various shapes, such as domes or hemispherical lenses. Although there is some ability to change lens shapes by changing mold blocks, the types and shapes of lenses that are manufacturable are limited by the ability to remove mold blocks from the lenses without damaging or otherwise changing the lens shape.

According to aspects of the present disclosure, complex lens shapes relative to support structures are provided by utilizing encapsulant materials with increased thixotropic properties and/or viscosity. Such encapsulant materials may be manipulated to achieve desired shapes for targeted emission profiles before curing. Since such encapsulant materials may hold their shape for curing without conventional molds, shape limitations associated with mold release may be avoided. In certain aspects, a complex lens shape includes a lens with a perimeter that extends beyond sidewalls of the support structure. In such configurations, sides of the lens may inwardly taper toward the support structure with a shape not possible with conventional molding. In further aspects, a complex lens shape may include an inward dimple or depression formed in a top surface thereof. The amount a lens extends beyond sidewalls of the support structure and/or dimensions of the inward dimple may be tailored to achieve desired emission patterns of the LED package. In certain aspects, emission patterns may be tailored to provide wider emission angles than conventional LED packages with dome lenses.

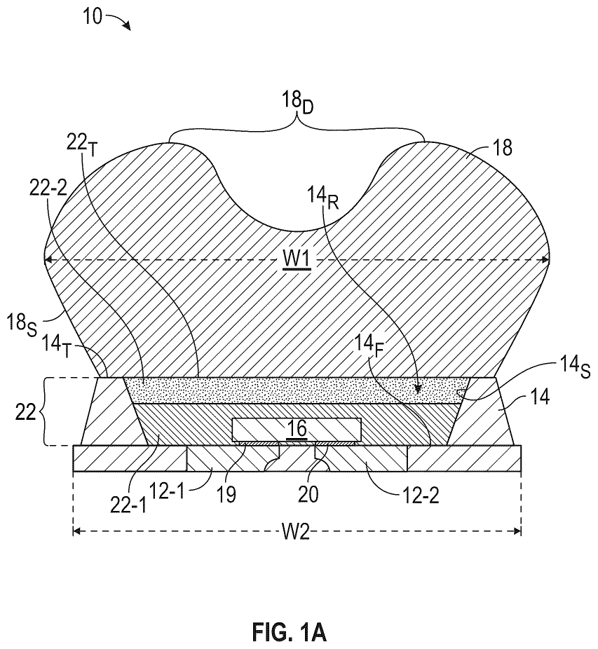

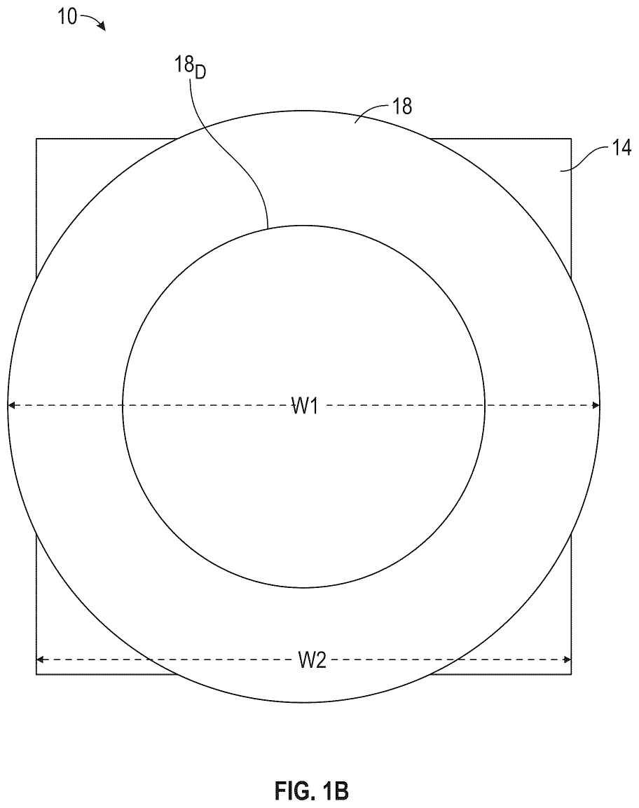

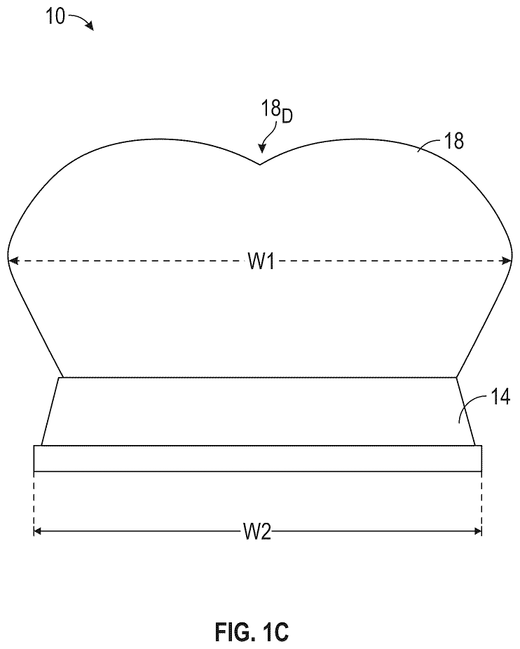

FIG. 1A is a cross-sectional view of an LED package 10 that includes a lead frame structure collectively formed by a plurality of leads 12-1 to 12-2, a body or housing 14 that encases a portion of the lead frame structure, at least one LED chip 16, and a lens 18 with a structure according to principles of the present disclosure. The LED chip 16 is positioned within a recess 14_{R} formed by the housing 14, and the LED chip 16 is electrically coupled to the leads 12-1 to 12-2. By way of example, the LED chip 16 is illustrated in a flip-chip configuration where anode and cathode pads 19, 20 of the LED chip 16 are mounted and electrically coupled to corresponding leads 12-1 and 12-2. In other embodiments, the LED chip 16 may be electrically coupled to at least one of the leads 12-1 and 12-2 by way of a wire bond. After the LED package 10 is fabricated, the LED package 10 may be subsequently bonded to another surface, such as within an LED display or other lighting device by way of portions of the leads 12-1 and 12-2 that extend outside a bottom of the housing 14. As illustrated, portions of the leads 12-1 and 12-2 may directly exit the bottom of the housing 14 for surface mounting. In other embodiments, portions of the leads 12-1 and 12-2 may exit lateral sides of the housing 14, bend along the lateral sides, and extend along portions of the bottom of the housing 14 for surface mounting.

The LED package 10 may further include an encapsulant layer 22 that at least partially fills the recess 14_{R} and covers the LED chip 16. As described above, a material of the encapsulant layer 22 may comprise silicone, epoxy, or PMMA. In certain embodiments, the encapsulant layer 22 may include first and second sublayers 22-1, 22-2 with different properties. For example, a first sublayer 22-1 may be arranged on a recess floor 14_{F} of the housing 14 and a second sublayer 22-2 may be formed on the first sublayer 22-1. The first and second sublayers 22-1, 22-2 may fill the recess 14_{R} and extend to one or more recess sidewalls 14_{S} of the housing 14. The recess sidewall 14_{S} may represent a single continuous sidewall that is continuously formed about a periphery of the recess 14_{R}, or several recess sidewalls 14_{S} may be joined together about the periphery of the recess 14_{R}. The first sublayer 22-1 may partially or fully encapsulate the LED chip 16. In certain embodiments, the first sublayer 22-1 may comprise a lumiphoric material, such as lumiphoric particles that have been permitted to settle within the recess 14_{R} and be closer to the LED chip 16 for wavelength conversion. In this manner, the first and second sublayers 22-1, 22-2 may both comprise a same material, such as silicone, that also serves as a binder for the lumiphoric particles of the first sublayer 22-1. In embodiments without lumiphoric materials or those where lumiphoric particles are present through the encapsulant layer 22, the encapsulant layer 22 may embody a single layer.

The LED package 10 further includes the lens 18 on the encapsulant 22. The lens 18 may further extend on portions of the housing 14 that are outside the recess 14_{R}. As illustrated, the lens 18 may be formed with a shape tailored for providing a wider emission pattern of light exiting the LED package 10. For example, the lens 18 may have a portion that laterally extends past side edges of the housing 14 and/or leads 12-1, 12-2. In this manner, a first width W1 may be defined as a longest lateral dimension of the lens 18 and a second width W2 may be defined as a longest lateral dimension of the housing 14. In order to increase light emissions in wider angle, the first width W1 may be greater than the second width W2. As such, the width of the lens 18 may progressively increase in a direction from a top surface 14_{T} of the housing 14 to the first width W1, thereby forming one or more sidewalls 18_{S} of the lens 18 that inwardly taper in a direction towards the top surface 14_{T} of the housing 14.

The lens 18 may further include a dimple or depression 18_{D} in a surface of the lens 18. As illustrated, the depression 18_{D} may form inward in a direction towards the LED chip 16. For example, the depression 18_{D} may form an inwardly curved surface that is effectively centered with respect to the LED chip 16. In this manner, increased light emissions that are normal to surface of the LED chip 16 may be redirected to wider angle emissions. From the cross-sectional view of FIG. 1A, the lens 18 may appear as a dual-dome lens with peaks of increased thickness on either side of the depression 18_{D}. In certain embodiments, the depression 180 may form a generally circular shape that is centrally located about the lens 18, such that the peaks of increased thickness visible in FIG. 1A represent a continuous ring that extends about and defines a perimeter boundary of the depression 18_{D}.

As described above, the material of the lens 18 may be provided with increased thixotropic properties and/or viscosity. In certain embodiments, the lens 18 is formed of a material with higher viscosity than a material of the encapsulant layer 22. In certain embodiments, both the lens 18 and the encapsulant layer 22 may generally comprise a same material, such as silicone, with the material of the lens 18 embodying a higher viscosity silicone than the silicone of the encapsulant layer 22. Additionally, the material of the encapsulant 22 may have a lower coefficient of thermal expansion than the lens 18 to provide increased softness and buffering of the LED chip 16 and corresponding electrical connections during heat cycling.

During fabrication, the encapsulant layer 22 may be first filled into the recess 14_{R}, followed by curing of the encapsulant layer 22. As described above, the encapsulant layer 22 may include a first sublayer 22-1 with settled lumiphoric particles. In such embodiments, the curing may be performed a sufficient time after dispensing to permit settling. After curing of the encapsulant layer 22, a top surface 22_{T} of the encapsulant 22 may provide a more planar surface for forming the lens 18. For embodiments where the top surface 22_{T} forms a generally planar surface, the top surface 22_{T} may form a slight curvature or meniscus between the recess sidewalls 14_{S} and a low point of the meniscus may be within 100 microns (μm), or within 50 μm, of the top surface 14_{T} of the housing 14, depending on a size of the recess 14_{R}. In such embodiments, the encapsulant layer 22 may still cover substantially all of the recess sidewalls 14_{S}, such as at least 90%, or at least 95%, or at least 99% of the recess sidewalls 14_{S}. The material of the lens 18 is provided with sufficiently high viscosity to permit the lens 18 to have a dispensed shape that is retained before curing. For example, the material of the lens 18 may be dispensed with increased pressure through a nozzle with a narrow orifice above the LED chip 16. The increased dispensing pressure may effectively be controlled to form the depression 18_{D} at a top surface of the lens 18. Adjustments to the dispensing pressure and/or width of the nozzle orifice may be utilized to tailor dimensions, such as a depth and/or width of the depression 18_{D} for achieving specific light emission patterns.

FIG. 1B is a top view of the LED package 10 of FIG. 1A. As illustrated, the first width W1 of the lens 18 laterally extends past perimeter edges of the housing 14 that define the second width W2. The lens 18 may form a circular shape at the first width W1. In certain embodiments, a perimeter of the depression 18_{D} may form a generally circular shape that is centrally located about the lens 18. Accordingly, the areas of increased thickness of the lens 18 form a continuous ring that extends about and defines a perimeter boundary of the depression 18_{D}. In certain embodiments, the housing 14 may form a square or rectangular shape from the top view and the lens 18 may extend outside all four perimeter edges of the housing 14.

FIG. 1C is a side view of the LED package 10 of FIG. 1A. From the side view, the full depth of the depression 18_{D} into the lens 18 may not be fully visible. Instead, only a small indentation at a top of the depression 18_{D} may visible due to the areas of increased thickness of the lens 18 essentially extending around a lateral perimeter of the depression 18_{D}.

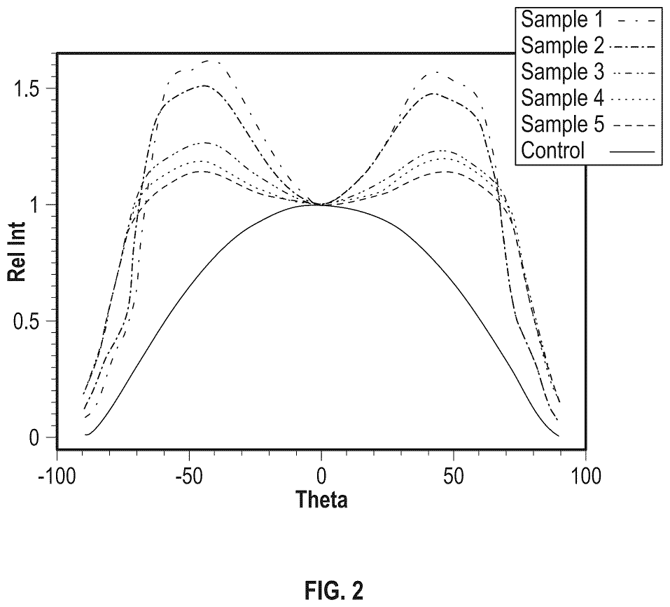

FIG. 2 depicts a graph of far-field patterns for various configurations of the LED package 10 of FIGS. 1A to 1C as compared to a control LED package without a lens. The x-axis represents various+/−theta values plotted in degrees, where theta=0 is a viewing angle directly above the LED package in a perpendicular direction with respect to a light-emitting surface of the LED chip. The y-axis represents relative light intensity in arbitrary units. In FIG. 2, a control LED package is provided that is similar to the LED package 10 but without the lens 18. In this regard, the top surface 22_{T} of the encapsulant layer 22 forms the light-exiting surface for the control LED package. As illustrated, the far-field emission pattern for the control LED package exhibits a profile where the peak light intensity is generally centered at or near theta=0. FIG. 2 also shows far-field emission patterns for various arrangements of the lens 18 and corresponding depression 18_{D} as illustrated in FIGS. 1A and 1B. In FIG. 2, the depth of the depression 18_{D} is progressively changed from a greatest depth for Sample 1 to shallowest depth for Sample 5. As illustrated, each of the Samples 1 to 5 exhibit peak light intensities that are offset from the theta=0 in positive and negative directions. The Sample 1 with the deepest depression 18_{D} exhibits large deltas between a light intensity at theta=0 versus peak light intensities proximate theta values of +/−40. Each subsequent LED package (Samples 2 to 5) with decreasing depths of the depression 18_{D} exhibit gradual reductions in this delta. Accordingly, emission patterns for LED packages of the present disclosure may be controlled and/or tailored for specific applications. By way of example, the Samples 1 and 2 may be well suited for applications that seek to avoid centered hot spots in light intensity, such as direct or indirect lighting structures for horticulture or architectural implementations. The Samples 3 to 5 with progressively flatter emission profiles may be well suited for panel lighting or backlighting applications where more even intensity distributions are required. All of the Samples 1 to 5 may avoid the need for the added complexity of secondary optics to achieve such emission patterns. Additionally, the wider peak emission patterns may permit LED packages to be spread farther apart while still providing sufficient lighting distributions, thereby saving overall system costs.

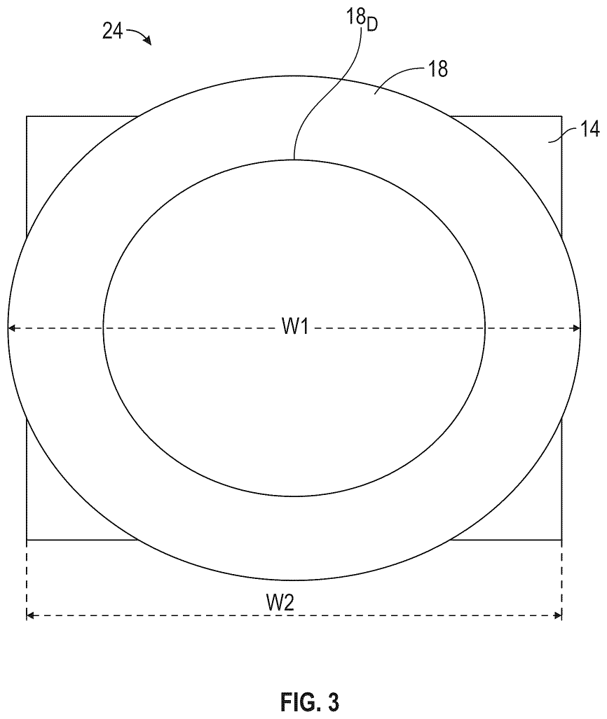

FIG. 3 is a top view of an LED package 24 that is similar to the LED package 10 of FIGS. 1A to 1C, except the lens 18 is formed with an oval shape. As illustrated, the lens 18 forms the oval shape at the first width W1. In certain embodiments, a perimeter of the depression 18_{D} may form a corresponding oval shape. Such oval shapes may be well suited to direct increased light intensities in two directions, such as left and right directions relative to the perspective of FIG. 3. In certain embodiments, the housing 14 may form a rectangular shape from the top view and the lens 18 may extend outside all four perimeter edges of the housing 14. As illustrated, the relationship between the relative widths W1 and W2 in FIG. 3 may be the same as described above for FIG. 1A.

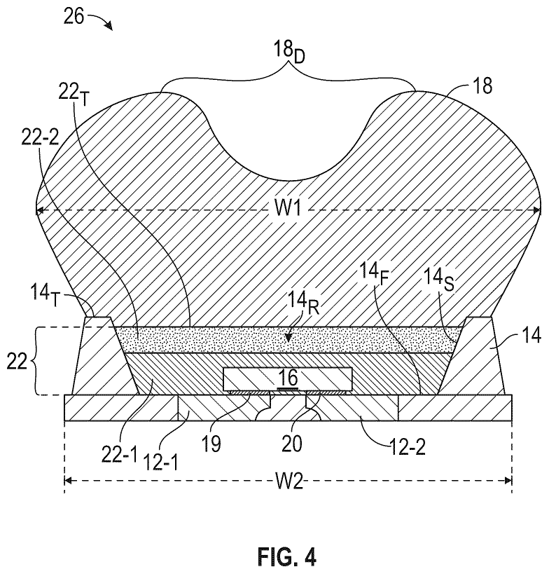

FIG. 4 is a cross-sectional view of an LED package 26 that is similar to the LED package 10 of FIGS. 1A to 1C, except the lens 18 is arranged to extend farther into the recess 14_{R}. In this regard, at least a portion of the lens 18 covers the one or more recess sidewalls 14_{S}. In certain embodiments, the encapsulant layer 22 may only cover a range from 50% to 90% of the recess sidewalls 14_{S} with the lens 18 covering at least a portion of the remainder of the recess sidewalls 14_{S}. By having the lens 18 extend into the recess 14_{R}, improved adhesion between the lens 18 and the housing 14 may be provided. As illustrated, the relationship between the relative widths W1 and W2 in FIG. 4 may be the same as described above for FIG. 1A.

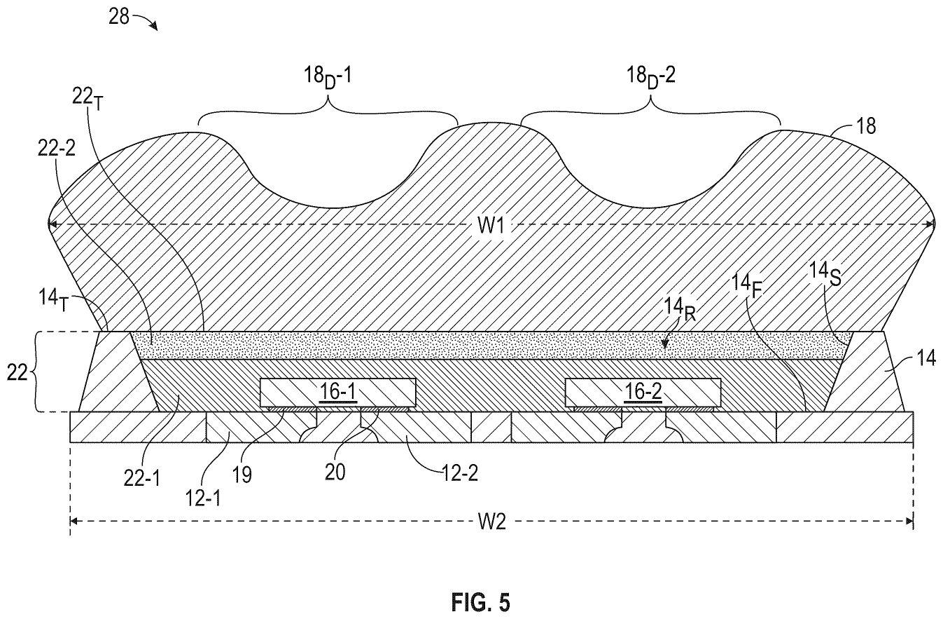

FIG. 5 is a cross-sectional view of an LED package 28 that is similar to the LED package 10 of FIGS. 1A to 1C, except the lens 18 forms multiple depressions 18_{D}-1, 18_{D}-2. In certain embodiments, the LED package 28 may include multiple LED chips 16-1, 16-2 within the recess 14_{R}, and the lens 18 may include separate depressions 180-1, 18_{D}-2 that are generally centered above a corresponding one of the LED chips 16-1, 16-2. Accordingly, individual emissions from each LED chip 16-1, 16-2 may exhibit off-centered peak intensities (i.e., offset from theta=0 of FIG. 2) within the same recess 14_{R}. The off-centered peak intensities from each LED chip 16-1, 16-2 may effectively overlap one another for improved color mixing in aggregate emissions exiting the LED package 28. As illustrated, the relationship between the relative widths W1 and W2 in FIG. 5 may be the same as described above for FIG. 1A.

While the previous embodiments are described in the context of lead frame support structures, the principles described are also applicable to support elements that include submounts with electrically conductive traces.

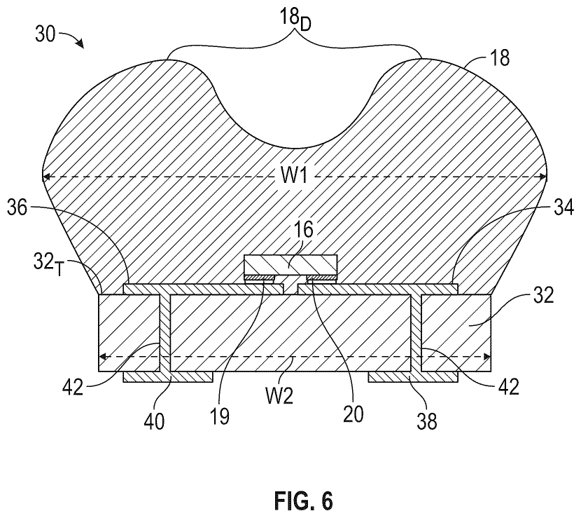

FIG. 6 is a cross-sectional view of an LED package 30 that is similar to the LED package 10 of FIGS. 1A to 1C, except the LED package 30 includes a submount 32 instead of a lead frame structure. The submount 32 may include electrically conductive top traces 34, 36 on a top surface 32_{T} thereof for electrically coupling with the anode and cathode pads 19, 20 of the LED chip 16. For flip-chip arrangements, the anode and cathode pads 19, 20 may be bonded to and electrically coupled to corresponding ones of the top traces 34, 36. For non flip-chip embodiments, at least one of the top traces 34, 36 may be coupled to the LED chip 16 by way of a wire bond. A bottom of the submount 32 may include package mounting pads 38, 40 in the form of electrically conductive bottom traces. The package mounting pads 38, 40 may provide electrical connections for mounting the LED package 30 to another surface, such as a printed circuit board of a larger device or system. A number of electrically conductive vias 42 may be provided within the submount 32 to provide electrically conductive pathways between the top traces 34, 36 and corresponding ones of the mounting pads 38, 40. The lens 18 may be formed on the LED chip 16 and on the submount 32 with the depression 18_{D} and with a same or similar shape as described above for the lens 18 of any of FIGS. 1A and 1B, FIG. 3, and FIG. 5 for multiple chip embodiments. Additionally, the width of the lens 18 may progressively decrease in a direction toward the top surface 32_{T}. The width W2 in FIG. 6 may define a widest width or longest lateral dimension of the support element formed by the submount 32. As illustrated, the relationship between the relative widths W1 and W2 in FIG. 6 may be the same as described above for FIG. 1A.

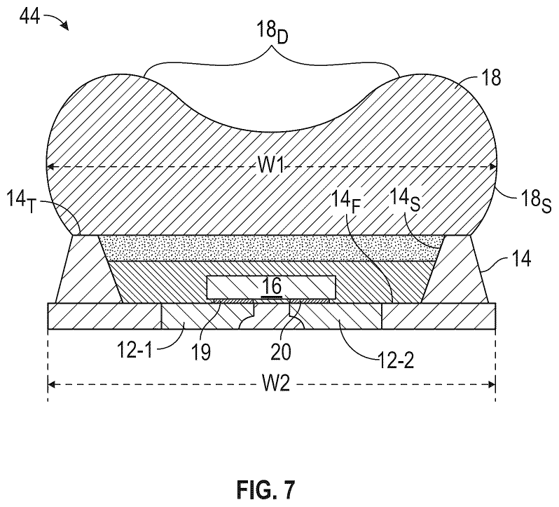

FIG. 7 is a cross-sectional view of an LED package 44 that is similar to the LED package 10 of FIGS. 1A to 1C with a different shape for the lens 18. In FIG. 7, the lens 18 is formed with more rounded or curved sidewalls 18_{S} that extend towards the top surface 14_{T} of the housing 14. An overall height of the lens 18 relative to the housing 14 may also be smaller than the LED package 10 of FIGS. 1A to 1C. In certain embodiments, the width W1 of the lens may be the same or similar to the width W2 of the housing 14, but the lens 18 may still laterally extend beyond a perimeter of the top surface 14_{T} of the housing 14. The lens shape for the LED package 44 may provide a different emission pattern for different targeted applications than the LED package 10 of FIGS. 1A to 1C. Accordingly, the principles of the present disclosure provide the ability to readily tailor dimensions and/or shapes of the lens 18 for different applications by way of the self-forming capabilities of the lens material.

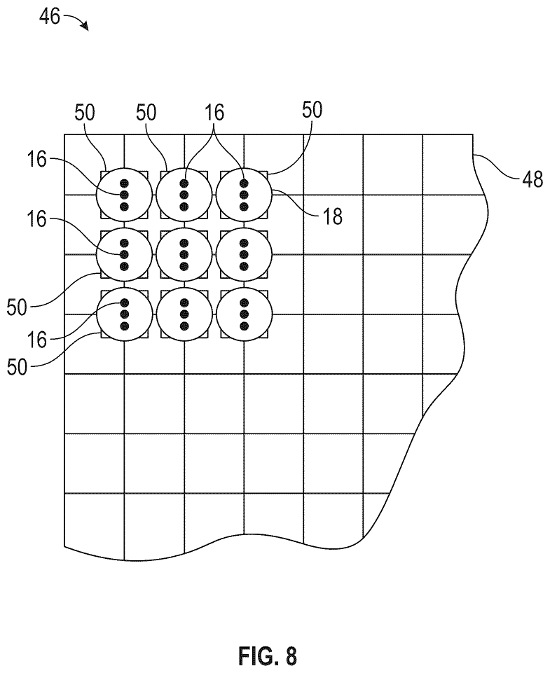

FIG. 8 is a schematic diagram of a portion of an LED device 46, such as a display screen, for example, an indoor and/or outdoor screen comprising, in general terms, a display panel including a driver printed circuit board (PCB) 48 carrying a large number of surface-mount devices (SMDs) 50 arranged in rows and columns, each SMD 50 defining a pixel. The SMDs 50 may comprise LED packages with lenses 18 as described above for any of the embodiments shown in FIGS. 1A to 7. The SMDs 50 are electrically connected to traces or pads on the PCB 48 to respond to appropriate electrical signal processing and driver circuitry (not shown). As disclosed above, it is to be appreciated that while FIG. 8 depicts the LED chips 16 in a linear arrangement within each LED package for the SMD 50, in other embodiments, the LED chips 16 may be arranged in different configurations.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a housing forming a recess with a recess floor;
a lead frame structure at least partially within the housing;
at least one LED chip positioned on the lead frame structure within the recess;
an encapsulant layer within the recess; and
a lens on the encapsulant layer and the housing, the lens having a first width that is greater than a second width of the housing.

2. The LED package of claim 1, wherein a surface of the lens forms an inward depression in a direction toward the at least one LED chip.

3. The LED package of claim 2, wherein the inward depression is centered with respect to the at least one LED chip.

4. The LED package of claim 3, wherein a perimeter of the inward depression forms a circular shape.

5. The LED package of claim 3, wherein a perimeter of the inward depression forms an oval shape.

6. The LED package of claim 1, wherein the encapsulant layer comprises a lower coefficient of thermal expansion than the lens.

7. The LED package of claim 1, wherein the recess forms at least one sidewall that extends to the recess floor, and the encapsulant layer covers at least ninety percent of the at least one sidewall.

8. The LED package of claim 1, wherein the recess forms at least one sidewall that extends to the recess floor, and the encapsulant layer covers a range from fifty to ninety percent of the at least one sidewall, and the lens covers at least a portion of the at least one sidewall.

9. The LED package of claim 1, wherein:
the encapsulant layer comprises a first sublayer and a second sublayer;
the first sublayer is between the recess floor and the second sublayer; and
the first sublayer comprises a higher concentration of lumiphoric particles than the second sublayer.

10. The LED package of claim 1, wherein the lens forms a circular shape at the first width.

11. The LED package of claim 1, wherein the lens forms an oval shape at the first width.

12. The LED package of claim 1, wherein:
the at least one LED chip comprises at least a first LED chip and a second LED chip;
a surface of the lens forms a first inward depression that is centered with respect to the first LED chip; and
the surface of the lens forms a second inward depression that is centered with respect to the second LED chip.

13. A light-emitting diode (LED) package comprising:
a support element;
at least one LED chip positioned on the support element; and
a lens on at least one LED chip and the support element, the lens forming a first width that is greater than a second width of the support element, and the lens further forming an inward depression in a direction toward the at least one LED chip.

14. The LED package of claim 13, wherein the inward depression is centered with respect to the at least one LED chip.

15. The LED package of claim 13, wherein:
the at least one LED chip comprises at least a first LED chip and a second LED chip;
the inward depression is a first inward depression that is centered with respect to the first LED chip; and
the lens further forms a second inward depression that is centered with respect to the second LED chip.

16. The LED package of claim 13, wherein the support element comprises a submount with electrically conductive traces.

17. The LED package of claim 13, wherein the support element comprises a lead frame structure at least partially within a housing.

18. The LED package of claim 17, further comprising an encapsulant layer between the lens and the at least one LED chip.

19. The LED package of claim 18, wherein the housing forms a recess with at least one sidewall that extends to a recess floor, and the encapsulant layer covers at least ninety percent of the at least one sidewall.

20. The LED package of claim 18, wherein the housing forms a recess with at least one sidewall that extends to a recess floor, and the encapsulant layer covers a range from fifty to ninety percent of the at least one sidewall, and the lens covers at least a portion of the at least one sidewall.
